(19) United States
(12) Patent Application Publication
(10) Pub. No.: US 2025/0306103 A1
(43) Pub. Date: Oct. 2, 2025

(54) CIRCUIT ARRANGEMENT FOR TESTING A BRIDGE CIRCUIT

(71) Applicant: Andreas Stihl AG & Co. KG, Waiblingen (DE)

(72) Inventors: Sascha Kälber, Aichwals (DE); René Wichert, Durlangen (DE); Ingo Kugler, Waiblingen (DE); Martin Fieseler, Essen (DE)

(21) Appl. No.: 19/091,658

(22) Filed: Mar. 26, 2025

(30) Foreign Application Priority Data
Mar. 26, 2024 (DE) 10 2024 108 666.1

(51) Int. Cl. G01R 31/327; H02M 7/537

(52) U.S. Cl. CPC G01R 31/3277; H02M 7/537

(57) ABSTRACT

A circuit arrangement is for testing a bridge circuit having an electronic low-side switch and an electronic high-side switch at a DC voltage for operating an EC electric motor. Between one low-side and one high-side switch, a switching node is configured, which is provided for connecting one phase to the EC electric motor. Via the low-side switch and the high-side switch of the bridge circuit, one phase of the EC electric motor is controlled. To check the bridge circuit for a short-circuit on a low-side switch or on a high-side switch, the switching node between the low-side switch and the high-side switch is connected to an auxiliary voltage source. The potential point is connected to a comparator assembly which compares the voltage potential of the potential point with a threshold voltage. In the event of an undershoot or overshoot of the threshold voltage, a signal indicating a short-circuit is generated.

### CROSS-REFERENCE TO RELATED APPLICATIONS

This application claims priority of German patent application no. 10 2024 108 666.1, filed Mar. 26, 2024, the entire content of which is incorporated herein by reference.

### TECHNICAL FIELD

The disclosure relates to a circuit arrangement for testing a bridge circuit including at least one low-side switch and one high-side switch at a DC voltage for operating an electronically commutated electric motor (EC electric motor).

### BACKGROUND

From US 2012/0249027, a test circuit is known for a bridge circuit, including at least one electronic low-side switch and one electronic high-side switch for operating an EC electric motor. Between an electronic low-side switch and an electronic high-side switch, in each case, a switching node (also described as a potential point) is configured. The switching node or potential point is configured as a phase terminal for connecting to the EC motor, wherein the low-side switch and high-side switch of the bridge control one phase of the EC motor. For the further phases of the EC electric motor, a further bridge circuit is configured in each case.

In the event of malfunctions of the high-side switch and/or of the low-side switch, unacceptable operating states can occur. If, for example, the high-side switch and the low-side switch of one phase are simultaneously closed, the DC voltage applied is short-circuited, which can result in consequential electrical damage and/or thermal damage. This state can occur, in the event that the high-side switch and/or the low-side switch is/are defective as a result of a short-circuit.

### SUMMARY

It is an object of the disclosure to detect, prior to the switch-on of the bridge circuit for operating the EC electric motor, that no short-circuit is present on any of the high-side switches and/or low-side switches of the bridge circuit.

For the fulfilment of this object, a circuit arrangement is proposed for testing a bridge circuit, including at least one low-side switch, in particular an electronic low-side switch, and one high-side switch, in particular an electronic high-side switch, at a DC voltage for operating an EC electric motor, wherein a switching node (potential point) is configured between the high-side switch and the low-side switch. The switching node or potential point forms a phase terminal for connecting to the EC electric motor, wherein the high-side switch and the low-side switch of the bridge control one phase of the EC electric motor. According to the disclosure, the switching node is connected, between the high-side switch and/or the low-side switch, particularly in a high-ohmic arrangement, to an auxiliary voltage source which supplies an auxiliary voltage. The switching node—in particular via a voltage divider—is connected to a comparator assembly which is appropriate for comparing the voltage potential of the switching node (potential point) with at least one threshold voltage or reference voltage. The comparator assembly is configured, in the event of an undershoot or overshoot of the at least one threshold voltage, to generate a failure signal. The failure signal indicates whether there is a short-circuit on the electronic low-side switch and/or on the electronic high-side switch. If a short-circuit is present, any further entry into service of the EC electric motor is inhibited.

In an embodiment according to the disclosure, the comparator assembly is configured to generate a first signal in the event of an undershoot of a lower threshold voltage, and to generate a second signal in the event of an overshoot of an upper threshold voltage. An undershoot and/or overshoot of the threshold voltage is detected if the threshold voltage is undershot or overshot by a technical factor, for example, advantageously of 1% to 5%.

It can be appropriate that the lower threshold voltage and/or the upper threshold voltage is/are dependent upon the magnitude of the DC voltage for operating the EC electric motor. In particular, the threshold voltages can be dependent upon the present operating voltage for driving the electric motor, and can be dynamically varied in accordance with the accumulator voltage. The threshold voltages can advantageously be generated via a microprocessor, or via voltage dividers, from the operating voltage for operating the electric motor.

Appropriately, the switching node (potential point) is connected to the comparator assembly via a voltage divider. The comparator assembly can include a discrete comparator circuit, a comparator or similar. The comparator assembly appropriately includes an integrated ADC (analogue-digital converter) in a microcontroller.

The auxiliary voltage of the auxiliary voltage source is lower, in particular lower by a multiple factor, than the DC voltage which is applied for operating the EC electric motor.

If the voltage which is tapped-off at the switching node, preferably via a voltage divider, is lower than the lower threshold voltage, a short-circuit is present on the low-side switch. If the voltage which is tapped-off at the switching node is higher than the upper threshold voltage, a short-circuit is present on the high-side switch. If the voltage which is tapped-off at the switching node overshoots the lower threshold voltage and undershoots the upper threshold voltage, a short-circuit is present on neither the high-side switch nor the low-side switch. In this manner, prior to the entry into service of the bridge circuit, a secure check can be executed as to whether a short-circuit is present on a high-side switch or on a low-side switch of the bridge circuit.

Ideally, a voltage is configured on the switching node (potential point) which proceeds from the high-ohmic auxiliary voltage applied, which voltage carries on-load circuit-related electric loads, in particular ohmic voltage dividers. The upper threshold voltage is required to lie between this ideal anticipated voltage and the operating voltage for operating the electric motor. The lower threshold voltage is required to lie below the ideal anticipated voltage. The margin between the upper and lower threshold voltage and the ideal value must be sufficiently large such that a further tolerable shunt connection (for example, associated with soiling or humidity) to the high-side switches or low-side switches, where the switches are intact, will not result in an undershoot of the lower limiting value or an overshoot of the upper limiting value.

The DC voltage for operating the EC electric motor is advantageously supplied by an accumulator. The DC voltage is an accumulator voltage.

The comparator assembly is advantageously configured, in the event of an undershoot of the lower threshold voltage, to generate a first signal which describes a short-circuit on the low-side switch, in particular a first failure signal. The comparator assembly is further configured, in the event of an overshoot of the upper threshold voltage, to generate a second signal which describes a short-circuit on the high-side switch, in particular a second failure signal.

In particular, the comparator assembly is configured to generate a third signal, in particular an “OK” signal, if the voltage potential of the switching node lies between the upper and lower threshold voltage.

In a further embodiment of the disclosure, the auxiliary voltage source is connected to the switching node via a resistance. It can further be appropriate that the auxiliary voltage source is configured such the current thereof can be electronically limited.

In a further embodiment of the disclosure, the low-side switch and high-side switch are respectively configured as electronic switches. Appropriately, the requisite trigger voltage for electronic switches forms the auxiliary voltage for the circuit arrangement for testing the bridge circuit. An electronic switch is periodically triggered by a driver or a driver circuit. The voltage generated and/or employed by the driver or the driver circuit can form the auxiliary voltage, or the auxiliary voltage can be derived therefrom. A separate auxiliary voltage source can thus be omitted.

An advantageous method for testing a bridge circuit including at least one low-side switch and one high-side switch at a DC voltage for supplying one phase for operating an EC electric motor and a switching node which is configured between the high-side switch and the low-side switch, for connecting one phase of the EC electric motor, is provided wherein, prior to the switch-on of the bridge circuit for operating the EC electric motor, an auxiliary voltage is applied to the switching node between the high-side switch and the low-side switch, in particular in a high-ohmic arrangement, which is not equal to the DC voltage for operating the EC electric motor. The voltage on the switching node is then measured, and the voltage on the switching node thus captured is compared with an upper threshold voltage an/or with a lower threshold voltage. In the event of an undershoot of the lower threshold voltage or an overshoot of the upper threshold voltage, a signal is generated which indicates the state of the high-side switch and/or of the low-side switch. If the voltage on the switching node lies between the lower threshold voltage and the upper threshold voltage, a third signal is generated, in particular an “OK” signal.

### BRIEF DESCRIPTION OF DRAWINGS

The invention will now be described with reference to the drawings wherein:

FIG. 1 shows a bridge circuit for the three-phase triggering of an EC electric motor at a DC voltage;

FIG. 2 shows a schematic bridge circuit according to FIG. 1, having a circuit arrangement for testing the bridge circuit;

FIG. 3 shows a schematic bridge circuit for one phase, having MOSFET switches and a driver circuit for triggering the MOSFETs, and a circuit arrangement for testing the bridge circuit;

FIG. 4 shows a schematic bridge circuit according to FIG. 3, having an additional resistance and a driver circuit, and a circuit arrangement for testing the bridge circuit;

FIG. 5 shows a schematic representation of a three-phase bridge circuit for triggering an EC electric motor at a DC voltage, with the energization of the motor phase V>W;

FIG. 6 shows a schematic representation of a three-phase bridge circuit core triggering an EC electric motor at a DC voltage, with the de-energization of the motor phase W>V; and,

FIG. 7 shows a schematic representation of a current characteristic during the testing of one motor phase.

### DETAILED DESCRIPTION

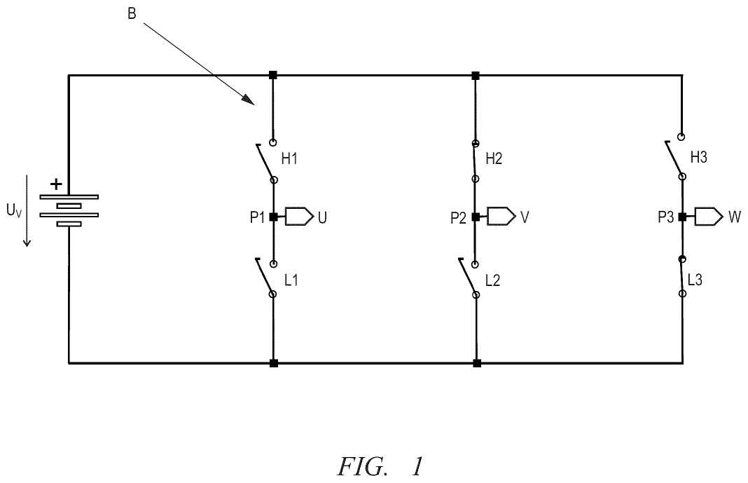

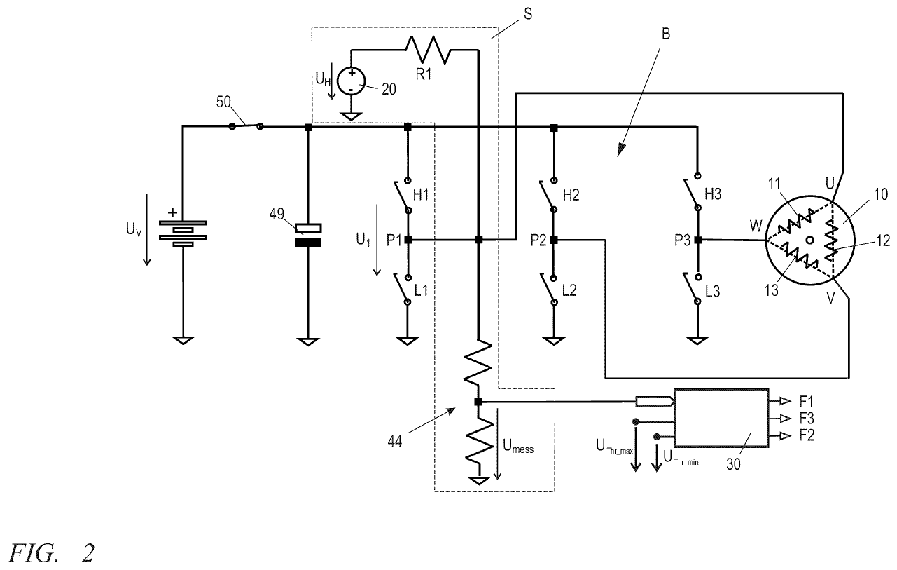

An EC electric motor 10 (FIG. 2), which is operated at a DC voltage U_{V}, is electronically triggered via an electronic bridge circuit B, as schematically represented in FIG. 1. For each phase U, V and W of the EC electric motor, in each case, a high-side switch H1, H2, H3 and a low-side switch L1, L2, L3 are configured. The switches are arranged in a “totem pole circuit”. Between one high-side switch H1, H2, H3 and one low-side switch L1, L2, L3, in each case, a switching node P1, P2, P3 is configured, to which the phases U, V and W of the EC electric motor are connected. A switching node of this type is also described as a potential point. Via a high-side switch H1, H2, H3, the positive pole of the supply voltage U_{V} can be applied to one phase U, V or W of the EC electric motor 10 (FIG. 2). Via a low-side switch L1, L2, L3, the negative pole of the supply voltage U_{V} can be applied to one phase U, V or W of the EC electric motor 10 (FIG. 2). As high-side switches or low-side switches, in particular, electronic switches are employed, and thus for example, semiconductor components such as MOSFETs or IGBTs.

The bridge circuit B represented in FIG. 1 is exemplarily configured as a three-phase bridge circuit. In this representation, the high-side switch H2 and the low-side switch L3 are closed. Phase U of the EC electric motor 10 does not assume any specific potential, as both the high-side switch H1 and the low-side switch L1 are open. Phase V of the EC electric motor 10 assumes a positive potential, and phase W of the EC electric motor 10 assumes a negative potential.

Via a control unit, which is not represented in greater detail, the high-side switches H1, H2, H3 and the low-side switches L1, L2, L3 are triggered, and a positive potential, a negative potential or an unspecified potential is optionally applied, in a mutually independent manner, to the phases U, V and W of the EC electric motor. The EC electric motor 10 is propulsively energized in this manner.

The control unit, which is not represented in greater detail, operates such that at no time are the high-side switch and the low-side switch of the same phase U, V or W simultaneously closed, as this would then result in a short-circuit of the supply voltage U_{V}. In the event of a short-circuit, consequential electrical damage or thermal damage can occur. A simultaneous switch-on of the high-side switch and the low-side switch of one phase U, V of W is securely prevented by the triggering process of the control unit. However, in the event of the failure of a high-side switch and/or of a low-side switch as a result of a short-circuit, notwithstanding an error-free triggering process, a short-circuiting of the supply voltage U_{V} can occur upon the entry into service of the EC electric motor.

In FIG. 2, according to the disclosure a circuit arrangement S is provided for testing the bridge circuit B, via, prior to the switch-on of an arbitrary high-side switch H1, H2, H3 and/or of an arbitrary low-side switch L1, L2, L3, a check can be executed to the effect that a short-circuit is not present on any of the high-side switches H1, H2, H3 and/or low-side switches L1, L2, L3.

The circuit arrangement S is configured to connect a switching node P1, P2 or P3 between a high-side switch H1, H2 or H3 and a low-side switch L1, L2 or L3 to an auxiliary voltage source 20. In the embodiment represented according to FIG. 2, the switching node P1 is connected to the auxiliary voltage source 20. The auxiliary voltage source 20 supplies an auxiliary voltage U_{H}. The auxiliary voltage U_{H} of the auxiliary voltage source is unequal to the DC voltage U_{V} for operating the EC electric motor 10. Advantageously, the auxiliary voltage U_{H} of the auxiliary voltage source assumes a magnitude which is lower, in particular lower by a multiple factor, than the DC voltage U_{V} for operating the EC electric motor. The circuit arrangement S is configured to connect the switching node P1 to a comparator assembly 30. The comparator assembly can be a discrete comparator circuit, a comparator, or similar. The comparator assembly appropriately includes an integrated ADC (analogue-digital converter) in a microcontroller.

The voltage U1 of the switching node P1 is preferably injected via a voltage divider 44 of the comparator assembly 30. The voltage which is tapped-off via the voltage divider 44 is identified in FIG. 2 as Uₘₑₛₛ. Via the comparator assembly 30, the voltage Uₘₑₛₛ which is tapped-off via the voltage divider 44 at the switching node P1 is compared with at least one threshold voltage U_{Thr}. By way of a threshold voltage U_{Thr}, a voltage is selected which is lower, in particular lower by a multiple factor, than the DC voltage U_{V} for operating the EC electric motor 10. The comparator assembly 30 is configured, in the event of an undershoot or overshoot of the threshold voltage U_{Thr}, to generate a signal F1 or F2. In particular, an upper threshold voltage U_{Thr_max} and a lower threshold voltage U_{Thr_min} are provided, with which the tapped-off voltage Uₘₑₛₛ is compared. The comparator circuit 30 is configured, in the event of an undershoot of the lower threshold voltage U_{Thr_min} or an overshoot of an upper threshold voltage U_{Thr_max} of the voltage Uₘₑₛₛ, to generate a signal F1 or F2.

In a simple manner, the auxiliary voltage U_{H}, via a resistance R1, is applied to the switching node P1, P2 or P3 of at least one phase U, V or W. In FIG. 2, the auxiliary voltage U_{H} is applied to the switching node P1 between the high-side switch H1 and the low-side switch L1 of phase U. If all the high-side switches H1, H2, H3 and low-side switches L1, L2, L3 are open, this auxiliary voltage U_{H} can be measured at the switching node P1 of phase U. Optionally, the voltage drop which is generated by the internal resistance of a measuring device or other electrical loads must be taken into consideration.

In the event that—as represented in FIG. 2—only one phase U is connected via a resistance R1 to the auxiliary voltage U_{H}, it can also be established whether an EC electric motor 10 is connected. If an EC electric motor 10 is connected, the auxiliary voltage U_{H} is also applied via the exciter coils 11, 12 and 13 of the EC electric motor 10 to the switching nodes P2, P3 of the other phases V and W, and can be measured.

Ideally, the following applies: if a short-circuit is present on a low-side switch L1, L2, L3 of one phase U, V or W, ideally, a voltage for example, of zero is measured on the switching node P1, P2 or P3 of this phase. If a short-circuit is present on a high-side switch H1, H2, H3, ideally, the DC voltage U_{V} which is applied for example, for operating the EC electric motor 10, is measured on the switching node P1, P2 or P3 of this phase. Only in the event that, ideally, the auxiliary voltage U_{H} applied is measured on the switching nodes P1, P2, P3, is a short-circuit present on none of the high-side switches H1, H2, H3 and/or of the low-side switches L1, L2, L3. A next step can be executed for the entry into service of the EC electric motor.

In practice, the circuit arrangement is configured such that the at least one switching node P1 between the low-side switch L1 and the high-side switch H1 is connected to the auxiliary voltage source 20, in particular in a high-ohmic arrangement. The switching node P1 is connected to a comparator assembly 30, which is appropriate for comparing the voltage Uₘₑₛₛ which is measured on the switching node P1 with an upper threshold voltage U_{Thr_max} and a lower threshold voltage U_{Thr} min. In the event of an undershoot of the lower threshold voltage U_{Thr_min}, a first signal F1 is generated for the indication of a short-circuit on the low-side switch and, in the event of an overshoot of an upper threshold voltage U_{Thr_max}, a second signal F2 is generated for the indication of a short-circuit on the high-side switch.

If an EC electric motor 10 is connected to the bridge circuit B, it can be sufficient that the auxiliary voltage U_{H} is injected at only one switching node P1, P2 or P3. As the phases U, V and W are interconnected via the exciter coils 11, 12, 13 of the electric motor 10, it can be established, via the measurement of voltage on only one switching node P1, P2 or P3, whether a short-circuit is present on one of the low-side switches L1, L2, L3 (undershoot of the lower threshold voltage U_{Thr_min}) or on one of the high-side switches H1, H2, H3 (overshoot of the lower threshold voltage U_{Thr_min}). An undershoot and/or overshoot of the threshold voltage is detected, if the threshold voltage is overshot or undershot by a technical factor, for example, advantageously of 1% to 5%.

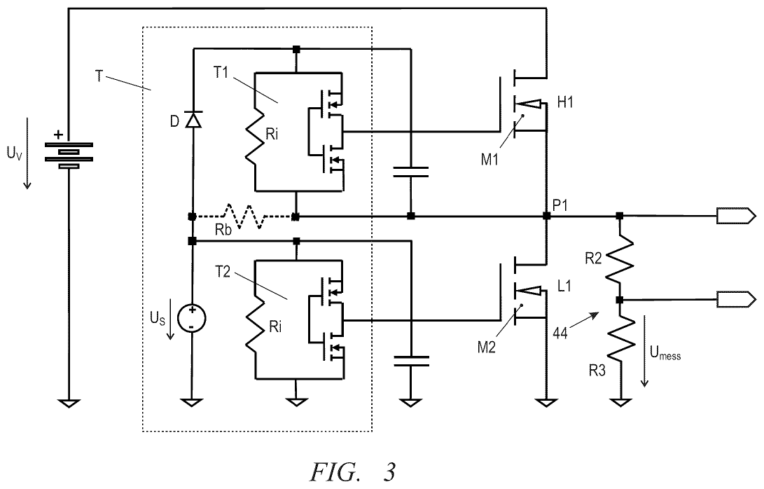

FIG. 3 shows an advantageous configuration of the circuit arrangement S for testing a bridge circuit B, including an electronic low-side switch L1 and an electronic high-side switch H1 at a DC voltage Uy. In the circuit layout according to FIG. 3, no additional electronic components are required. In FIG. 3, exemplarily, the triggering of one phase via MOSFETs M1 and M2, by way of an electronic high-side switch H1 and low-side switch L1, is represented.

Advantageously, a circuit element T is an integrated component of the circuit arrangement S for triggering the MOSFETs. This element can include the driver circuits T1 and T2.

For triggering the MOSFETs M1 and M2, a trigger voltage Us is provided. This trigger voltage Us is required for the driver circuits T1 and T2, and is generated on each EC electronic circuit. This trigger voltage Us is required for the operation of the electronic circuit itself.

Advantageously, the auxiliary voltage U_{H} is sourced from the trigger circuit. Via the bootstrap diode D and the internal resistance of the high-side driver circuit T1, the trigger voltage Us is applied to the switching node P1 of phase U. The voltage divider 44, included of R2 and R3, is present on each EC electronic circuit, and can be co-employed for the circuit arrangement S according to the disclosure.

Further components can be added to the circuit arrangement S. If, for example, the internal resistance Ri of the high-side driver circuit T1 is too high, an additional resistance Rb can be inserted between the trigger voltage Us and the switching node P1 of phase U. The additional resistance Rb is represented in FIG. 3 by a broken line. In this configuration of the circuit arrangement S, the resistance Rb corresponds to the resistance R1 in FIG. 2.

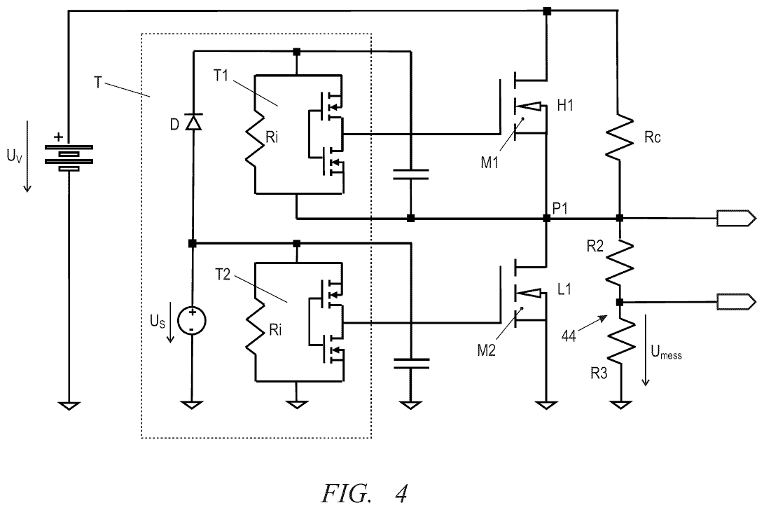

In a further embodiment according to FIG. 4, a resistance Rc can also be inserted between the DC voltage U_{V} (or an intermediate circuit voltage) and the switching node P1 of phase U.

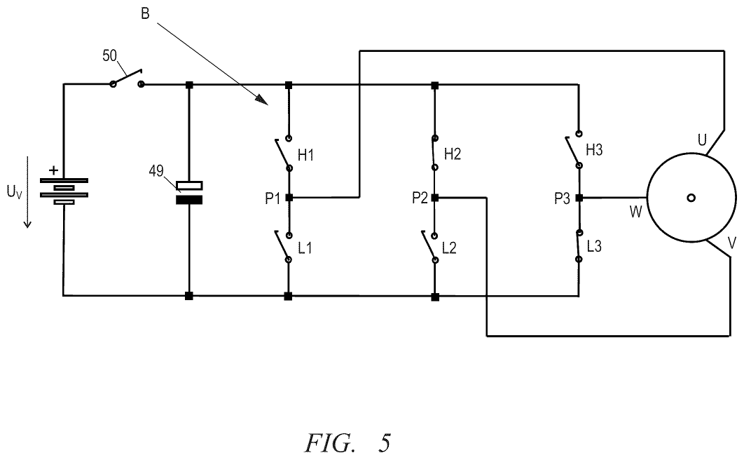

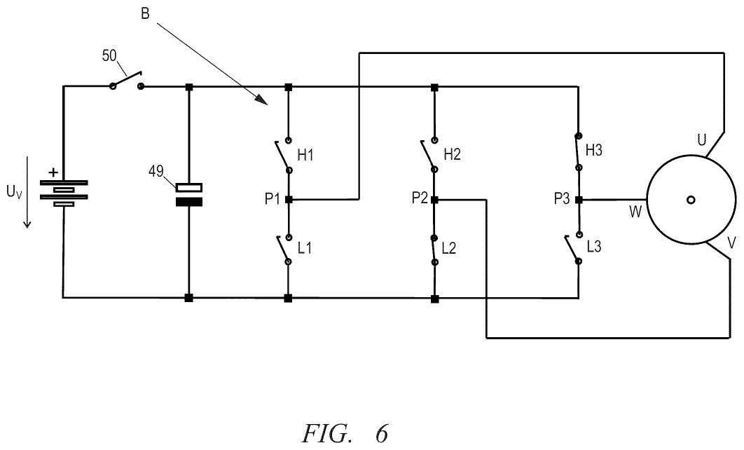

Further to the testing of the bridge circuit B via the circuit arrangement S according to the disclosure, prior to the entry into service of the EC electric motor 10, a further test procedure can be executed. To this end—as represented in FIGS. 5 and 6—by closing the switch 50, with the high-side switches H1, H2, H3 and low-side switches L1, L2, L3 in the open state, the capacitor 49 of an intermediate circuit which is arranged in parallel with the DC voltage U_{V} is charged, and is then isolated again from the DC voltage U_{V}. In particular, the DC voltage U_{V} is supplied by an accumulator.

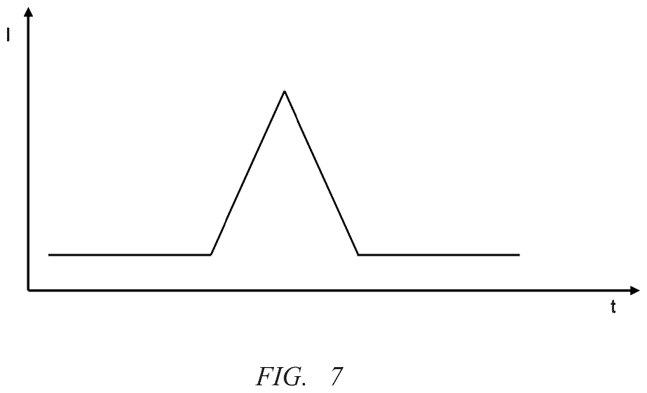

Then, in each case for a short time interval, one high-side switch H2 and one low-side switch L3 in one phase V/W are switched on, as exemplarily represented in FIG. 5. As a result, one phase V>W of the EC electric motor 10 is energized. The high-side switch H2 and the low-side switch L3 of one motor phase are closed. From the rate of rise of the phase current I—as represented in FIG. 7—the inductance of the active motor phase can be ascertained. Thereafter—as represented in FIG. 6—the same motor phase is de-energized again by closing the respectively opposing low-side switch L2 and high-side switch H3.

This method enables confirmation to the effect that all motor phases are connected, that no short-circuit is present in the motor, and that all high-side switches and low-side switches are operating in a fault-free manner.

A method according to the disclosure for testing a bridge circuit B having at least one low-side switch L1, L2, L3 and one high-side switch H1, H2, H3 at a DC voltage U_{V} for supplying one phase U, V, W for the operation of an EC electric motor 10 operates as follows. Between the high-side switch H1, H2, H3 and the low-side switch L1, L2, L3, at least one switching node P1, P2, P3 is configured, which is configured for connecting one phase U, V, W of the EC electric motor 10. The low-side switch L1, L2, L3 and the high-side switch H1, H2, H3 of the bridge circuit B are configured for controlling one phase U, V, W of the EC electric motor 10. Prior to the switch-on of the bridge circuit B for operating the EC electric motor 10, an auxiliary voltage U_{H} is applied to a switching node P1, P2, P3 between the high-side switch H1, H2, H3 and the low-side switch L1, L2, L3 in, particular in a high-ohmic arrangement. A voltage Uₘₑₛₛ of the switching node P1, P2, P3, which is advantageously tapped-off via a voltage divider 44, is compared with at least one, and advantageously with two threshold voltages, namely, a lower threshold voltage U_{Thr_min} and an upper threshold voltage U_{Thr_max}. In the event of an undershoot of the lower threshold voltage U_{Thr} min or in the event of an overshoot of the upper threshold voltage U_{Thr_max}, a signal F1 or F2 is generated, wherein the signal F1 or F2 indicates the state of the high-side switch H1, H2, H3 and/or of the low-side switch L1, L2, L3.

If the voltage Uₘₑₛₛ on the switching node P1, P2, P3 which is tapped-off, in particular via the voltage divider 44 lies below the upper threshold voltage U_{Thr_max} and above the lower threshold voltage U_{Thr_min}, a third signal F3 is generated. This third signal F3, in particular, is an “OK” signal.

It is understood that the foregoing description is that of the preferred embodiments of the invention and that various changes and modifications may be made thereto without departing from the spirit and scope of the invention as defined in the appended claims.

1. A circuit arrangement for testing a bridge circuit including at least one low-side switch and at least one high-side switch at a DC voltage for operating an EC electric motor, at least one switching node being configured between the at least one low-side switch and the at least one high-side switch, and the at least one switching node forming a terminal for connecting one phase on the EC electric motor, the at least one low-side switch and the at least one high-side switch of the bridge circuit controlling at least one phase of the EC electric motor, the at least one switching node being connected to an auxiliary voltage source having an auxiliary voltage, the circuit arrangement comprising:
a comparator assembly connected to the at least one switching node and configured to compare a voltage potential of the at least one switching node with at least one threshold voltage;
said comparator assembly being configured, in an event of an undershoot or overshoot of the at least one threshold voltage, to generate a signal; and,
the at least one low-side switch and the at least one high-side switch each being an electronic switch, wherein a requisite trigger voltage for the electronic switches forms the auxiliary voltage.

2. The circuit arrangement of claim 1, wherein said comparator assembly is configured, in the event of the undershoot of a lower threshold voltage, to generate a first signal and, in the event of the overshoot of an upper threshold voltage, to generate a second signal.

3. The circuit arrangement of claim 2, wherein at least one of the lower threshold voltage and the upper threshold voltage are dependent upon a magnitude of the DC voltage for operating the EC electric motor.

4. The circuit arrangement of claim 1, wherein the at least one switching node is connected to said comparator assembly via a voltage divider.

5. The circuit arrangement of claim 1, wherein said comparator assembly is configured, in the event of the undershoot of a lower threshold voltage by the voltage potential of the at least one switching node, to generate a first signal which represents a short-circuit on the at least one low-side switch; and, said comparator assembly is configured, in the event of the overshoot of an upper threshold voltage by the voltage potential of the at least one switching node, to generate a second signal which represents a short-circuit on the at least one high-side switch.

6. The circuit arrangement of claim 5, wherein the first signal is a first failure signal; and, said second signal is a second failure signal.

7. The circuit arrangement of claim 1, wherein said comparator assembly is configured to generate a third signal, if the voltage potential of the at least one switching node lies below an upper threshold voltage and above a lower threshold voltage.

8. The circuit arrangement of claim 7, wherein the third signal is an OK signal.

9. The circuit arrangement of claim 1, wherein the auxiliary voltage of the auxiliary voltage source is lower than the DC voltage for operating the EC electric motor.

10. The circuit arrangement of claim 1, wherein the auxiliary voltage of the auxiliary voltage source is lower by a multiple factor than the DC voltage for operating the EC electric motor.

11. The circuit arrangement of claim 1, wherein the auxiliary voltage source is connected to the at least one switching node via a resistance.

12. The circuit arrangement of claim 1, wherein a current of the auxiliary voltage source is electronically limited.

13. The circuit arrangement of claim 9, wherein an electronic switch is triggered by a driver circuit, and a voltage which is at least one of generated and employed by the driver circuit forms the auxiliary voltage.

14. The circuit arrangement of claim 1 further comprising a circuit element configured to supply the auxiliary voltage.

15. The circuit arrangement of claim 1, wherein the at least one switching node is connected to the auxiliary voltage source having the auxiliary voltage in a high-ohmic arrangement.

16. A method for testing a bridge circuit having at least one low-side switch and at least one high-side switch at a DC voltage for supplying one phase for operating an EC electric motor, wherein at least one switching node is configured between the at least one high-side switch and the at least one low-side switch for connecting one phase of the EC electric motor, and the at least one low-side switch and the at least one high-side switch of the bridge circuit control one phase of the EC electric motor, the method comprising:
prior to the switch-on of the bridge circuit for operating the EC electric motor, applying an auxiliary voltage to the at least one switching node;
comparing a voltage on the at least one switching node which is tapped-off via a voltage divider with at least one of an upper threshold voltage and a lower threshold voltage; and,
in an event of at least one of an undershoot of the upper threshold voltage and an overshoot of the lower threshold voltage, generating a signal which indicates a state of at least one of the at least one high-side switch and the at least one low-side switch.

17. The method of claim 16, wherein a further signal if the voltage which is tapped-off on the at least one switching node lies below the upper threshold voltage and above the lower threshold voltage.

18. The method of claim 17, wherein the further signal is an “OK” signal.
